(19) United States
(12) Patent Application Publication
(10) Pub. No.: US 2018/0090471 A1
(43) Pub. Date: Mar. 29, 2018

(54) Package on Package Structure Having Package To Package Interconnect Composed of Packed Wires Having A Polygon Cross Section

(71) Applicant: INTEL CORPORATION, Santa Clara, CA (US)

(72) Inventors: Chia-Pin CHIU, Tempe, AZ (US); Yoshihiro TOMITA, Tsukuba-shi (JP); Yoko SEKIHARA, Ibaraki (JP); Robert L. SANKMAN, Phoenix, AZ (US)

(21) Appl. No.: 15/279,353

(22) Filed: Sep. 28, 2016

(51) Int. Cl. H01L 25/10; H01L 25/00

(52) U.S. Cl. CPC H01L 25/105; H01L 2225/1052; H01L 2225/1041; H01L 25/50

(57) ABSTRACT

An apparatus is described that includes a package on package structure. The package on package structure includes an interposer to implement electrical interconnections between an upper package of the package on package structure and a lower package of the package on package structure. The interposer has packed wires, the packed wires have respective polygonal cross sections.

### FIELD OF INVENTION

The field of invention pertains generally to the semiconductor arts, and, more specifically, to a package on package structure having package to package interconnect composed of packed wires having a polygon cross section.

### BACKGROUND

The semiconductor arts has traditionally faced the challenge of attempting to integrate electronic functionality into as small a volume as possible. Package on package structures have recently emerged as a popular packaging technology for integrating multiple semiconductor die into a same semiconductor package.

### FIGURES

A better understanding of the present invention can be obtained from the following detailed description in conjunction with the following drawings, in which:

FIG. 1 shows a package on package structure;

FIG. 2 shows a packing density of stacked ball structures;

FIG. 3 shows increasing package-to-package interconnect density with decreasing interconnect pitch;

FIG. 4 shows packing density of square metal wires;

FIG. 5a shows an embodiment of an interposer for a package-on-package structure composed of packed square wires;

FIG. 5b shows a side view of a package-on-package structure having an interposer composed of packed square wires as the package-to-package interconnect;

FIG. 5c shows a top down of the lower package of the package-on-package structure of FIG. 5b;

FIG. 5d shows a detailed view of a cross section of an embodiment of an interposer composed of packed square wires;

FIGS. 6a through 6e show a first method of manufacturing a package-on-package structure;

FIGS. 7a through 7e show a second method of manufacturing a package-on-package structure;

FIGS. 8a through 8e show a method of manufacturing an interposer composed of tightly packed square wires;

FIG. 9 shows an embodiment of a computing system.

### DETAILED DESCRIPTION

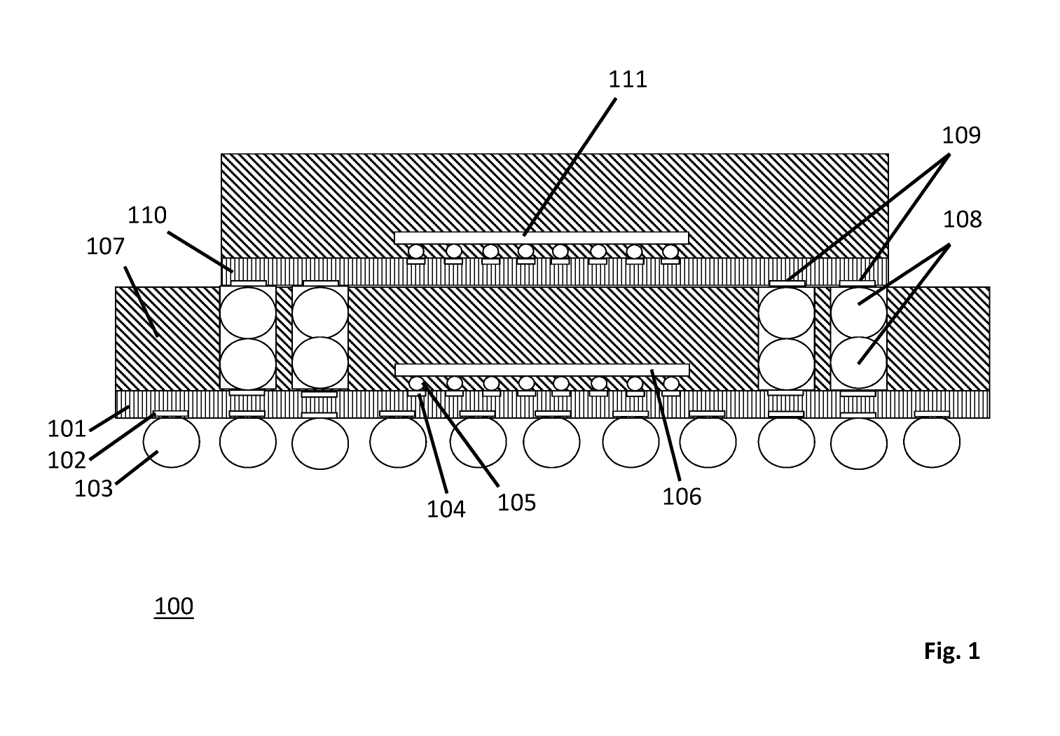

FIG. 1 shows a traditional package on package (PoP) structure 100. As observed in FIG. 1, a traditional package on package structure 100 includes a lower substrate 101 having pads 102 and solder balls 103 on its underside for connection of the overall PoP structure to whatever system it is being designed into (e.g., the PC board of a DIMM card or the mother board of a computing system).

Pads 104 and collapsed micro-solder balls 105 reside on the upper surface of the lower substrate 101 to electrically connected a lower die 106 to the top surface of the lower substrate 101. The lower die 106 is encapsulated with a mold compound 107. Off the periphery of the lower die 106, stacked solder ball structures 108 within through mold vias (TMVs) form an electrical connection (through mold interconnect (TMI)) between the lower substrate 101 of the PoP structure and the I/O pads 109 on the underside of an upper substrate 110 of an upper packaged die 111 that is mounted on the lower packaged die 106.

As semiconductor chip minimum feature dimensions continue to shrink, die sizes may become smaller which should provide for smaller package-on-package structures. However, also because of the smaller minimum feature sizes, the number of I/Os that a die may entertain can increase. For example, a memory die with reduced minimum feature size may integrate more storage cells and therefore may be designed to include more address lines. The increased number of I/Os, in turn, causes a need for more stacked solder ball structures such as structure 108 within the package on package structure 100.

Another semiconductor die manufacturing trend that is driving package-to-package interconnect upwards in PoP structures is the emergence of three dimensional monolithic semiconductor circuits. As an example, some memory technologies are building the storage cells in the interconnect metallurgy rather than within the semiconductor substrate. As a consequence, the storage cells are not only arranged in arrays in a same plane, but arrays of storage cells are stacked on top of one another to produce a three dimensional memory array rather than a two dimensional memory array. As with reduced minimum feature sizes, the emergence of three dimensional circuits is also integrating more function into a single die which can increase the I/O count of an upper die 111, which, in turn, drives the number of package to package interconnects 108 in a package on package structure 100 upward.

A problem with traditional PoP structures is the spatial inefficiency of the stacked solder ball 108 technology. Specifically, stacked solder ball technology has a relatively large pitch (e.g., approximately 0.4 mm to 0.5 mm). Stacked solder ball pitch, as is understood in the art, is the distance between the respective centers of two neighboring stacked solder ball structures.

As such, the packing density of the package-to-package interconnect 108 within a package-on-package structure is not keeping up with the increasing number of package-to-package interconnects 108 that need to be integrated into the PoP structure 100. As such, more and more of the footprint dimensions of a PoP structure 100 is determined by the interconnect structures 108 that surround the lower die 106 rather than the surface area dimensions of the die 106.

The relatively large pitch of the stacked solder ball 108 solution is generally due to the immaturity of through mold via technology. Further still, the solder balls 108 themselves have a relatively large height (e.g., 0.3 mm per solder ball which corresponds to a stacked solder ball structure of approximately 0.6 mm). Here, note that reducing the dimension of the solder balls, e.g., to effect smaller pitch for higher interconnect packing density, can also result in stacked solder ball heights that are not high enough.

With a stacked solder ball structure 108 height of approximately 0.6 mm, the entire package-on-package structure from the top of the upper package to the bottom of the lower package die can have a total height of approximately 1.0 mm which may be too high for certain applications (especially handheld device applications). Alternative solutions to stacked solder balls, such as wire bonding or high copper pillars (HCP) do not demonstrate significantly better pitch tolerances at least over stacked solder ball 108 structures.

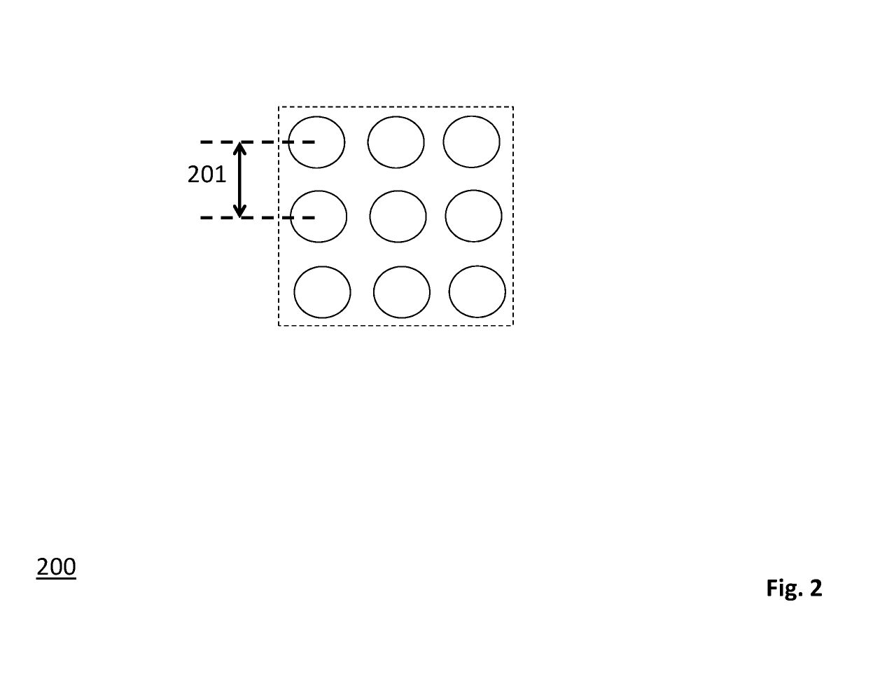

FIG. 2 shows a generalized top down view 200 of the packing density of the stacked solder ball structures within a package-on-package structure. Here, the wide pitch 201 corresponds to fewer interconnects over the depicted surface area.

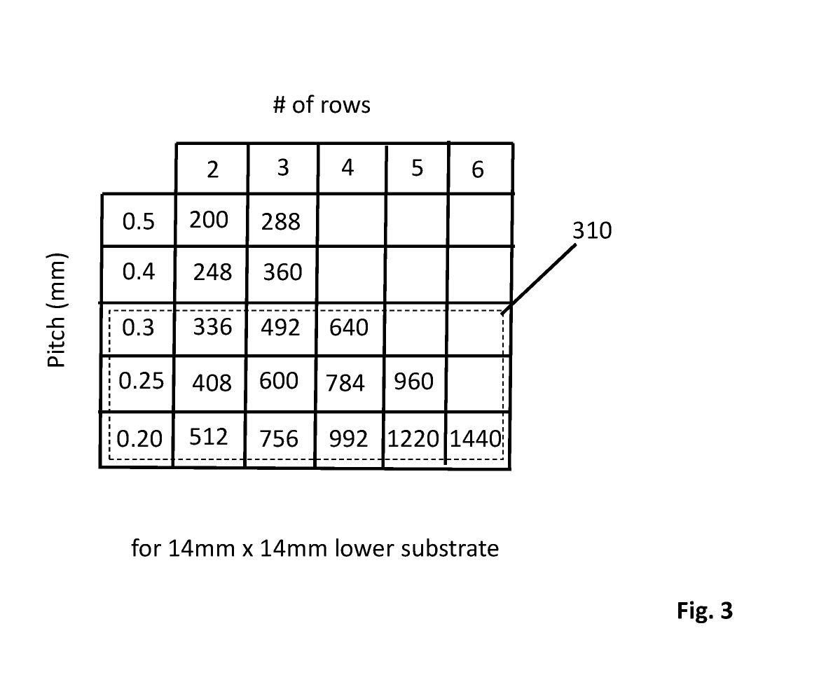

FIG. 3 shows the results of a study that demonstrate that the number of package-to-package interconnects within a package-on-package structure can increase significantly if package-to-package pitch dimensions can be aggressively reduced to values under 0.5 mm. Of particular note is that the interconnects themselves are generally arranged in rows (as observed in FIG. 2) but the number of rows that can be entertained diminishes with increasing pitch. For instance, as observed in FIG. 3, for a 14 mm×14 mm lower substrate dimension, only three rows of package-to-package interconnects can be entertained if the interconnect pitch dimensions are 0.5 mm or 0.4 mm.

However, with pitch reduction improvements of 0.3 mm, 0.25 mm and 0.2 mm, the number of rows that can be supported on the same sized lower substrate increases to four rows, five rows and six rows, respectively. Here, each additional row that can be integrated into the package corresponds to an entire row's worth of additional interconnections. Additionally, also generally observed in FIG. 3, reduced pitch allows for more interconnects per row (note that with falling pitch the interconnect count still increases for a same number of rows). As observed in FIG. 3 the increase in interconnections with reduction in pitch is dramatic (a 0.25 mm pitch technology can support approximately three to four times as many interconnects as a 0.5 mm pitch technology).

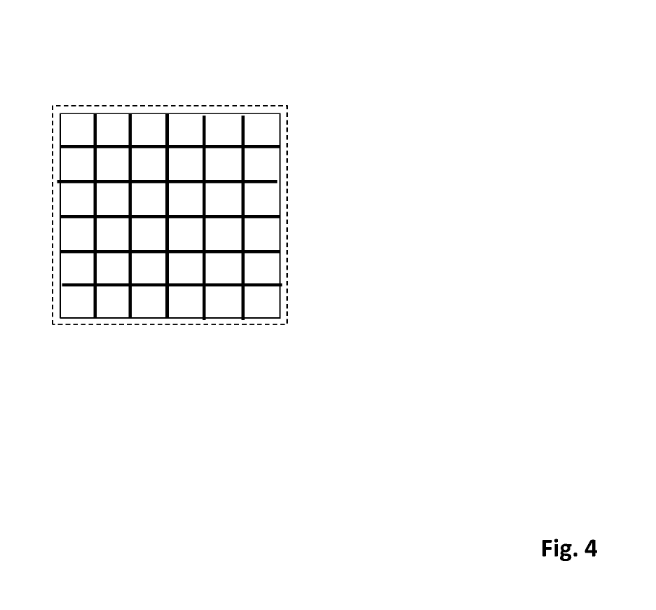

FIG. 4 shows a top down view of an improved approach that closely packs small square metal wires together to effectively lower the interconnect pitch. The new design creates a noticeably improved packing density as compared to the approach of FIG. 2. Specifically, just from a simple count of the interconnects in FIGS. 2 and 4, note that the approach of FIG. 4 provides a 6× interconnect packing density improvement over the same surface area as compared to the approach of FIG. 2. That is, FIG. 2 shows only nine interconnects whereas FIG. 4 shows 36 interconnects over the same surface area.

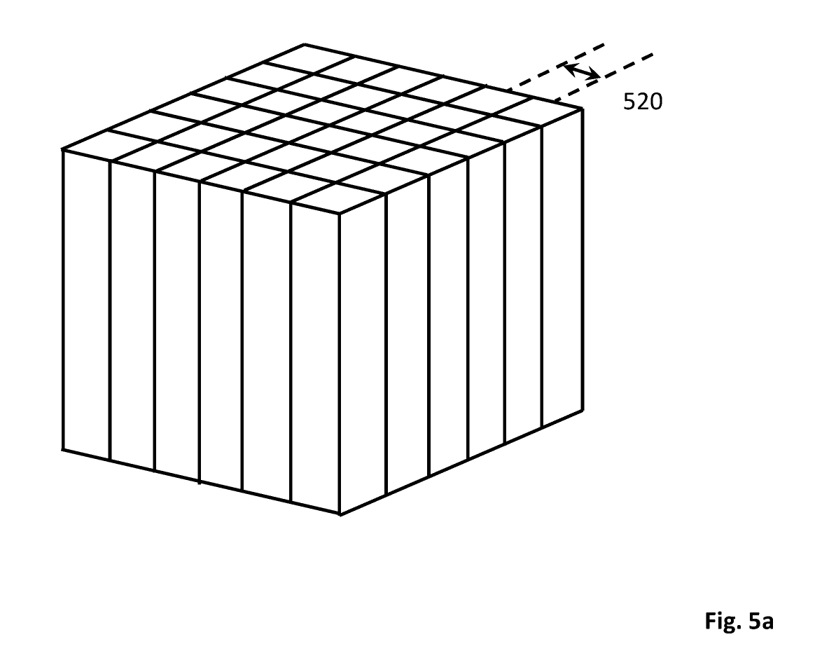

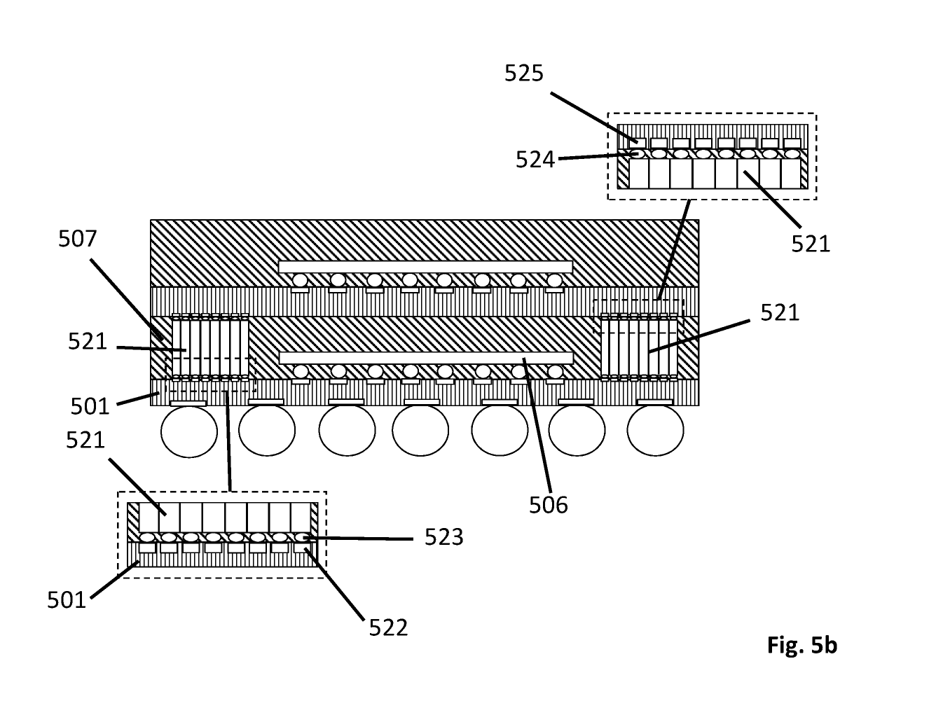

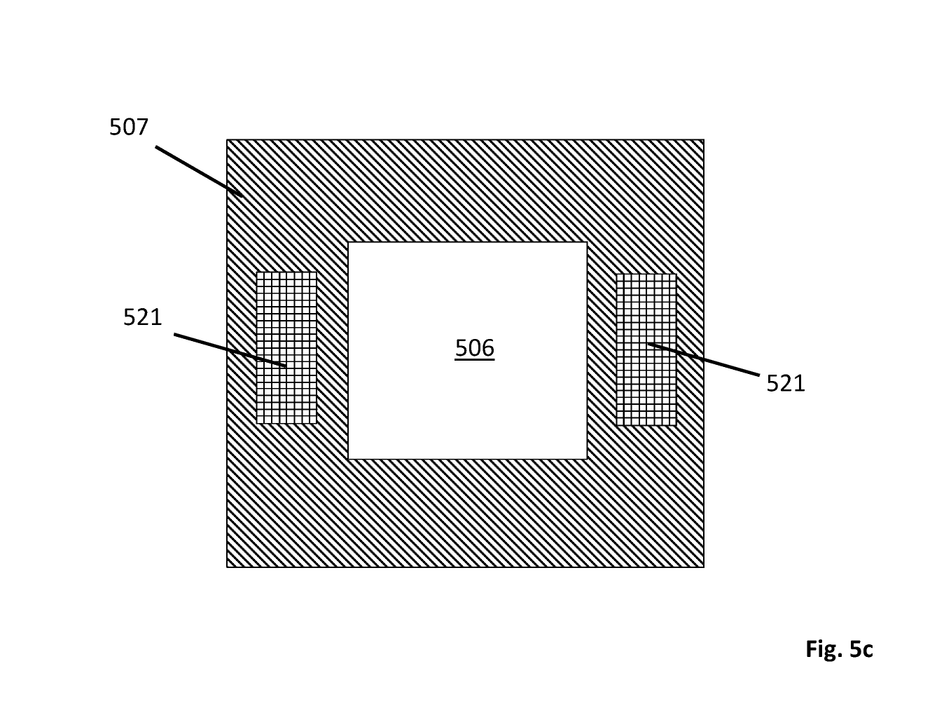

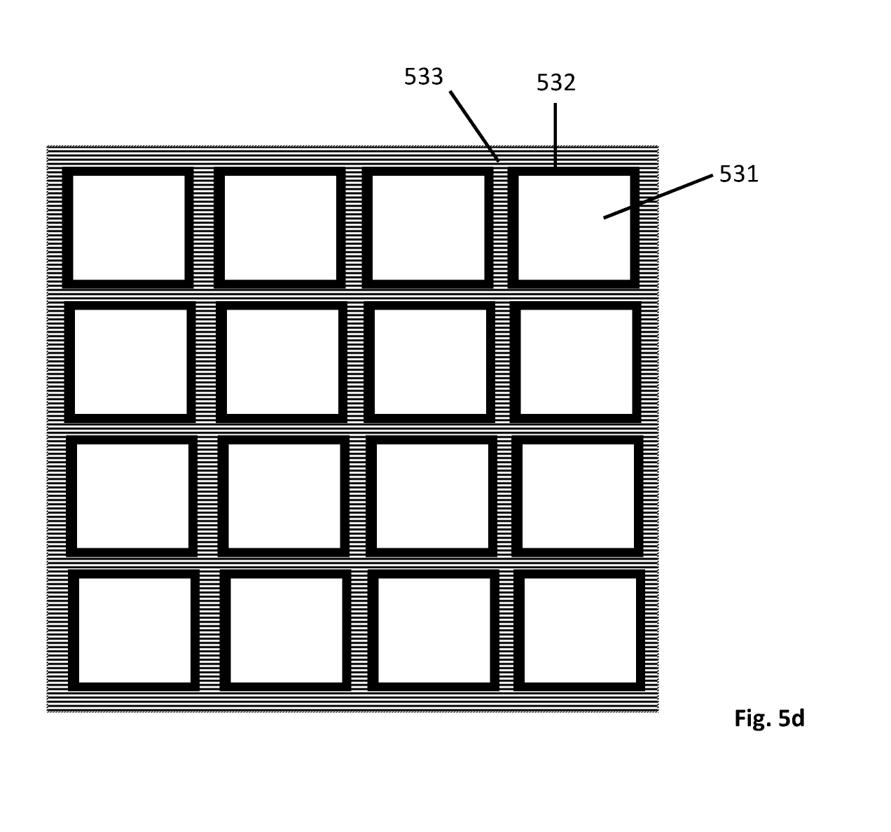

FIG. 5a shows a three-dimensional view of an interposer composed of tightly packed small square metal wires. FIGS. 5b and 5c show cross sectional and top-down views respectively of an embodiment of a package-on-package structure having interposers composed of tightly packed small square metal wires (such as the interposer of FIG. 5a) as the upper package to lower package interconnects (instead of stacked solder balls).

As can be seen in FIG. 5a, the square shape of the wires provides for tightly packing them together in a stable three dimensional structure. In an embodiment, each of the wires is surrounded by an insulating jacket or sleeve (hereinafter, simply “jacket”) and the compaction of the wires is secured through an adhesive material that resides between the insulating jackets of the wires. In various embodiment, the square wires themselves may be procured from a vendor that manufactures square copper wires such as Goto Denshi corporation having headquarters in Yamagata, Japan. A discussion of a possible approach for manufacturing the interposer from the square wires is provided in more detail below.

In an embodiment, the square wires have a cross width distance 520 of less than 0.2 mm which approximately corresponds to a wire-to-wire pitch of 0.2 mm. With interconnect pitches of less than 0.3 mm, interconnect densities such as those enumerated in region 310 of FIG. 3 are achievable for a 14 mm×14 mm footprint size. Even higher interconnect densities are achievable with pitches as low as approximately 0.1 mm.

FIG. 5b shows a cross-sectional view of a package on package structure having interposers 521 composed of packed square wires. Comparing FIG. 5b with FIG. 1, note that the package-on-package structure of FIG. 5b has a smaller footprint and vertical profile compared to the package-on-package structure of FIG. 1. For ease of drawing, the particular embodiment of FIG. 5b shows only two interposers 521 on either side of the lower die. In an alternate embodiment, more than two interposers may be integrated into the package-on-package structure, e.g., four interposers—one of each side of the lower die.

The particular embodiment of FIGS. 5b and 5c also show the existence of a mold compound 507 that encapsulates the lower die 506. However, in various embodiments, the mold 507 surrounding the lower die 506 may not be present. Here, being composed practically of solid metal, the interposers 521 by themselves possess the density/hardness needed to mechanically support the upper package. As such, empty space rather than a mold compound 507 may reside within the lower die package between the lower die 506 and the interposers 521.

According to the embodiment of FIGS. 5b and 5c, each of the interposers 521 is electrically connected with, e.g., micro solder balls or bumps 523 that were, e.g., preformed on an array of pads 522 formed on the upper surface of the lower package substrate 501. In various embodiments (that include or do not include mold compound 507), a top side lid may be placed over the lower die 506 to hermetically seal the lower die 506 and form a complete lower package structure. For ease of drawing a top side lid is not observed in FIG. 5b.

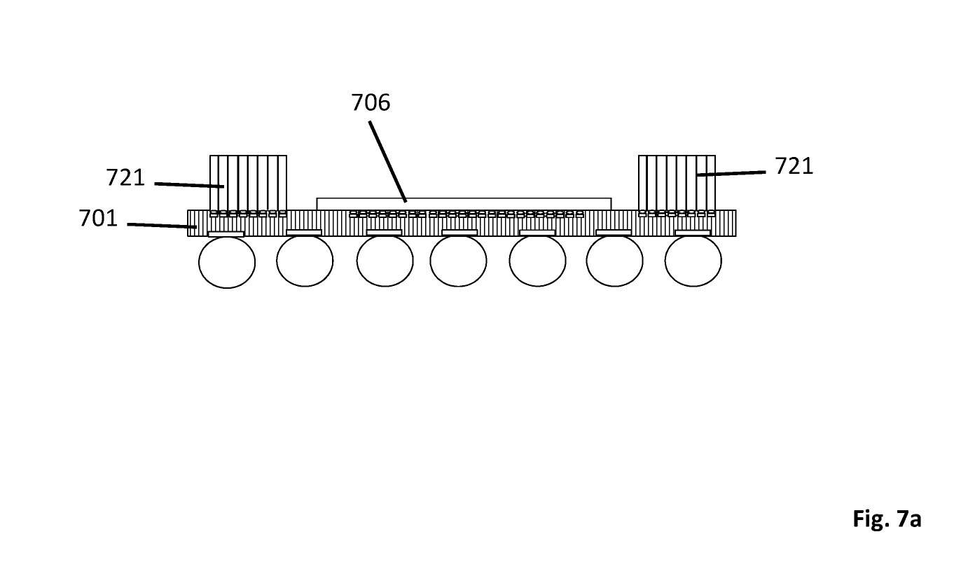

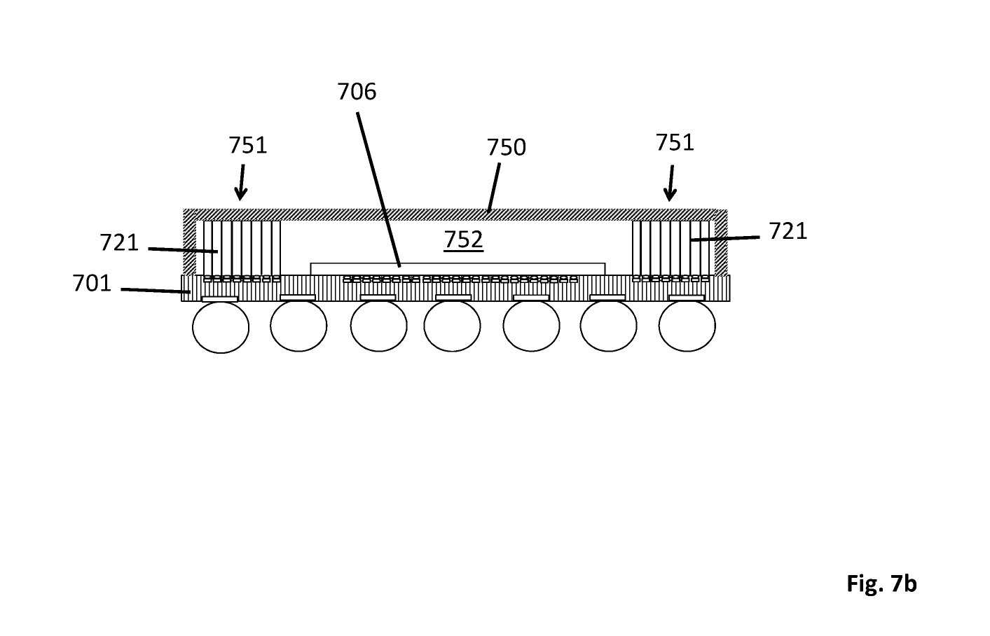

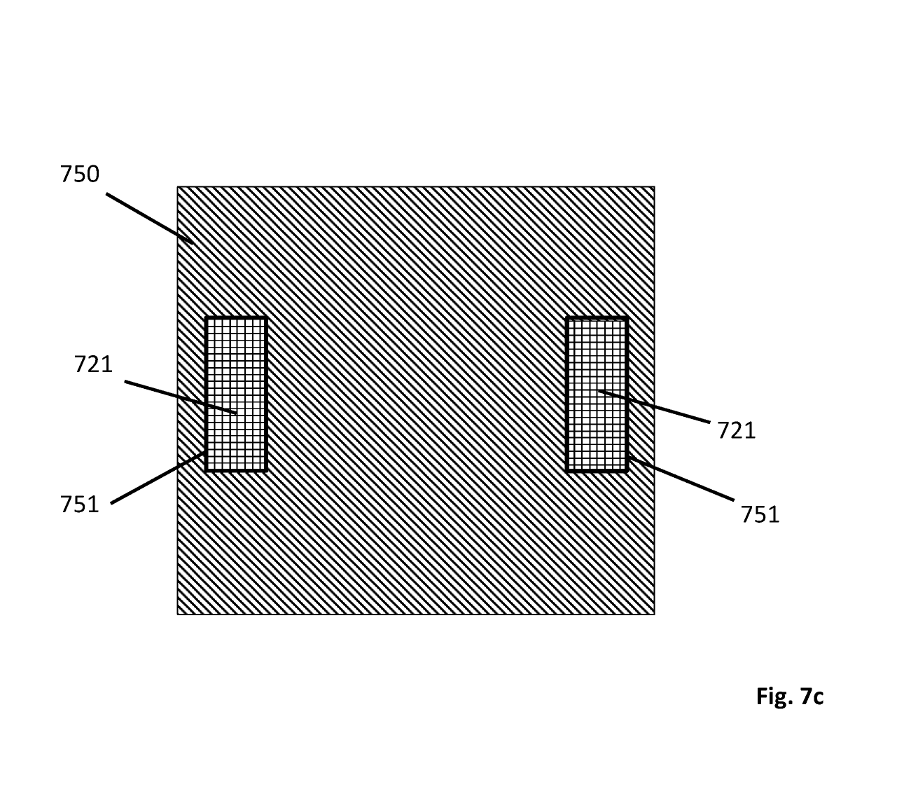

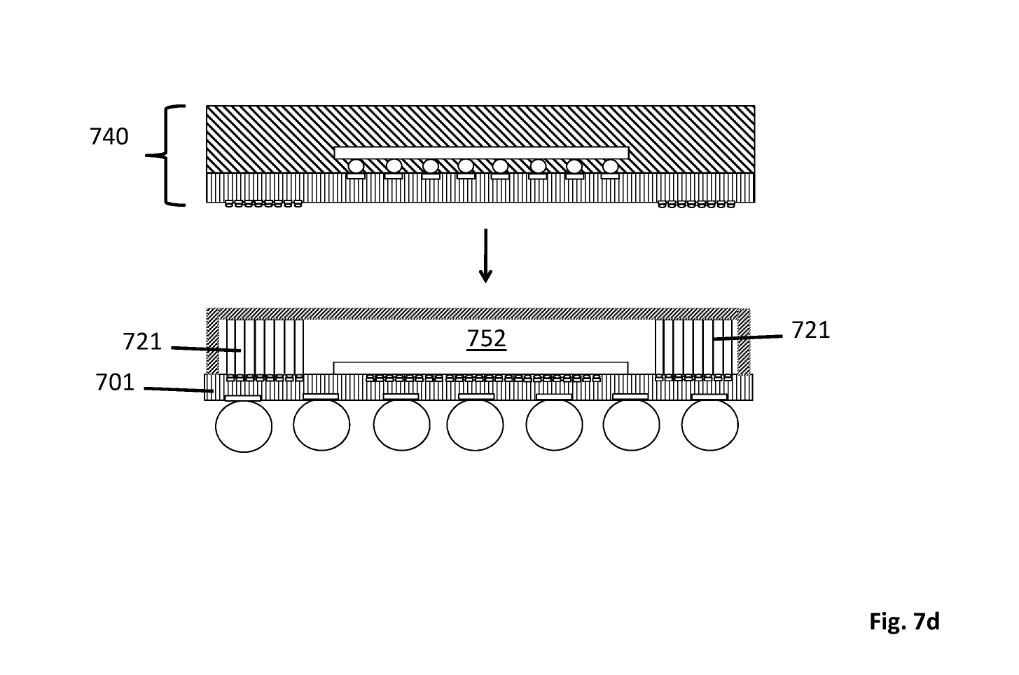

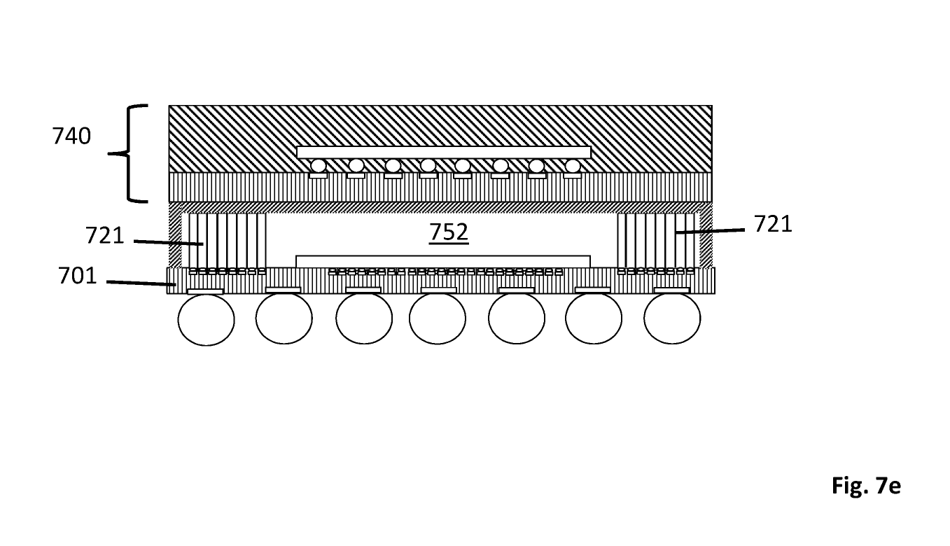

In embodiments having a top side lid, the top side lid may have openings to expose the upper faces of the interposers 521 which act as the topside I/O for the lower package. In such embodiments, one or more outer layers of the stacked wires of the interposers 521 are not used an electrical contacts but rather as a landing area for such a topside lid. Here, an adhesive may be applied on the landing area to ensure hermetic sealing of the lower package around the openings in the lid where the interposers are exposed. More details concerning application of a top side lid to a lower package are described below with respect to FIGS. 7a through 7c

The bottom-side I/Os 525 of the upper package are mounted directly onto the exposed interposers 521 (with, e.g., solder balls/bumps 524 in sandwiched in between). For the upper package connection, in an embodiment, solder bumps/balls 524 are placed on pads 525 formed on the bottom side of the substrate of the upper package.

FIG. 5c shows a top down view of the lower package structure. Again, for simplicity, only two interposers 521 are shown off opposite sides of the lower die 506. Alternate embodiments may exist where four interposers exist, e.g., one off each of the four sides of the die. In still yet other embodiments, such an embodiments that include a larger surface area lower substrate there may be multiple interposers off the side of the die (such as an embodiment having eight interposers, two off each of the four sides of the die). In alternate or combined embodiments there may even be interposers placed in the corner regions of the lower substrate 501. Note that although FIG. 5a shows that interposers may be cubic in form, by contrast, FIG. 5c indicates that interposers may be rectangular or otherwise oblong.

FIG. 5d shows a closer detail drawing of a cross section of an embodiment of an interposer. Here, insulation 532 around each square wire 531 and an adhesive 533 used to bind the bundle of square wires together are both clearly visible.

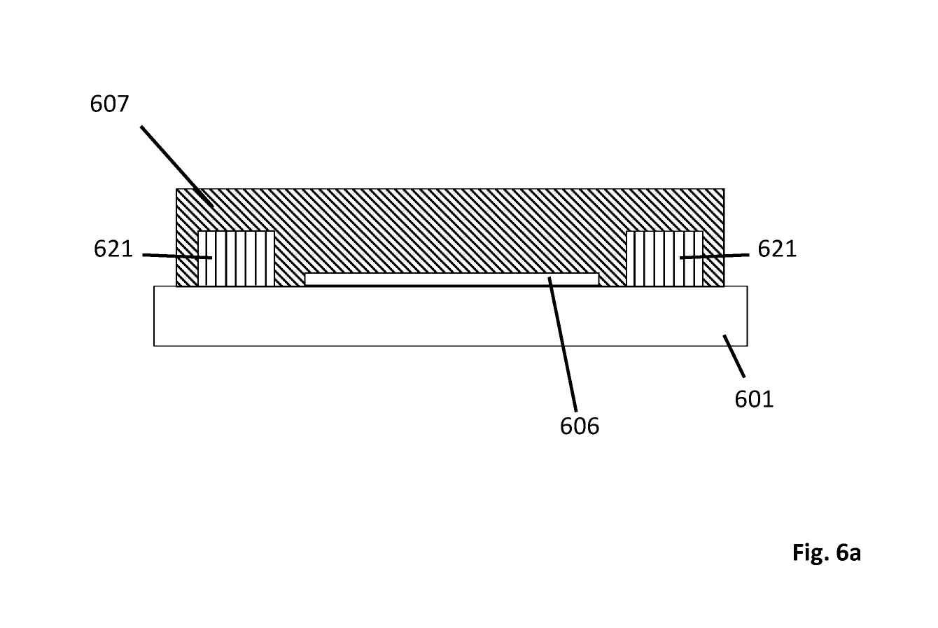

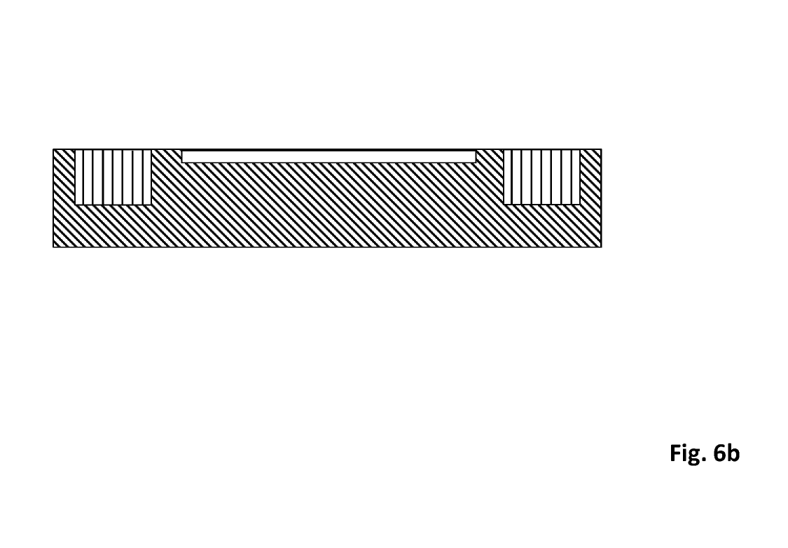

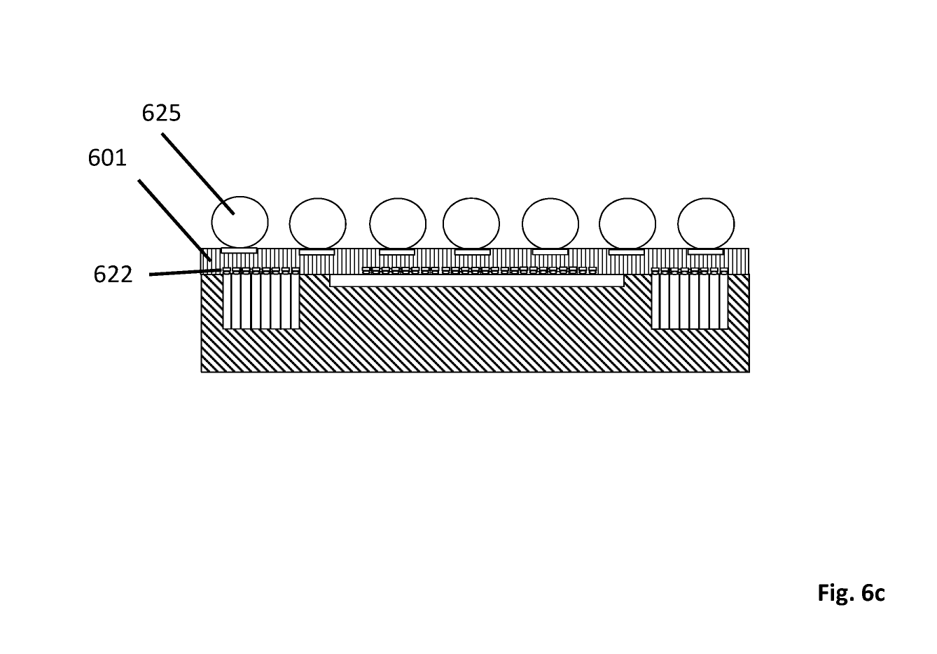

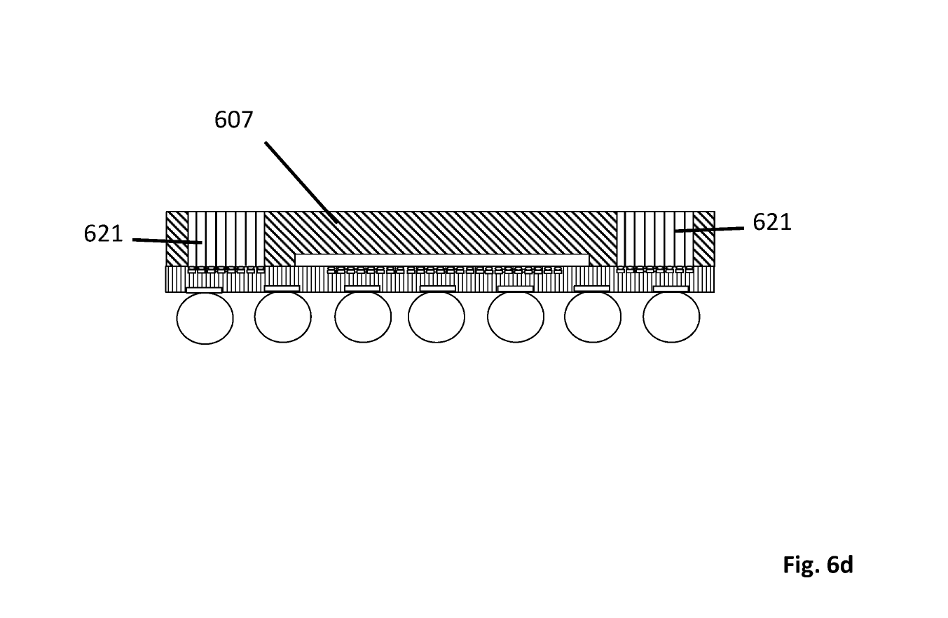

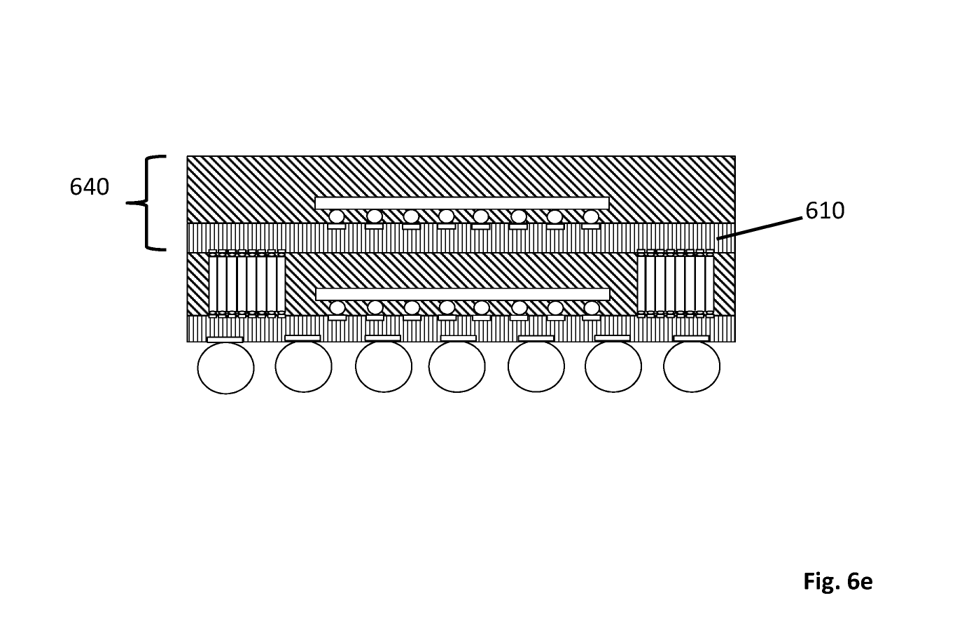

FIGS. 6a through 6e depict a first method of forming a package on package structure having stacked square wire interposers as described above.

As observed in FIG. 6a, the lower die 606 and interposers 621 are first mounted onto a carrier 601. Then, a mold compound 607 is applied to surround to the die 606 and interposers 621. As observed in FIG. 6b, the structure is inverted, the carrier 601 is removed and the lower substrate 601 is formed on the exposed surface where the carrier used to be attached. The lower substrate 601 includes electrical I/O pads 622, e.g., with preformed solder bumps/balls, that align to pads on the lower die and the exposed surfaces of the interposer wires. I/O balls 625 for the overall package-on-package structure are formed on exposed on pads on the opposite of the lower substrate than pads 622.

As observed in FIG. 6c, after the lower substrate 601 is formed, the structure is again inverted and the mold 607 is etched/grounded to expose the top surfaces of the interposers 621. As observed in FIG. 6d, the upper package 640 is aligned and lowered onto the lower package. Again, solder bumps/balls may be preformed on the underside of the upper package's substrate 610, the top faces of the interposers, or, some combination of both. The structure of FIG. 6d is then heated to collapse the balls/bumps so as to form the complete package-on-package structure.

FIGS. 7a through 7c depict a second method of forming a package on package structure having stacked square wire interposers as described above.

Referring to FIG. 7a, the lower die 706 and the interposers 721 are mounted on the substrate 701 of the lower package. Solder bumps/balls reside between the pad I/Os on the die's underside and corresponding, aligned pad I/Os on the lower substrate's top surface. Likewise, solder bumps/balls reside between the respective lower faces of the individual wires of the interposers and corresponding aligned pads on the lower substrate's top surface.

Where the solder/balls are preformed may vary from embodiment to embodiment. For example, in some embodiments all solder balls/bumps are formed on the underside of the die and the interposer, in other embodiments all solder balls/bumps are formed on the topside of the lower substrate, in yet other embodiments, some solder balls/bumps are formed on the underside of the die or interposer whereas other solder balls/bumps are formed on the topside of the lower substrate.

In various embodiments, as alluded to above, to attach an interposer 721 to the lower substrate 701, the interposer 721 is placed over a pad array formed on the top surface of lower substrate 701 in an aligned fashion. That is, for example, in an embodiment where the solder balls/bumps are preformed on the pad array, the lower face of each square wire of the interposer 721 is aligned with its own respective pad array location and corresponding solder bump/ball. The interposer 721 is then lowered onto the array of bumps/balls such that each square wire face rests on its corresponding bump/ball.

The ambient is then heated to collapse the bumps/balls and electrically connect each square wire face to its corresponding pad. In an embodiment, the ambient is flash heated to a higher than usual temperature so that each bump/ball associated with a particular interposer 721 collapses at approximately the same time or, at least, an attempt is made to limit the time difference between when outer balls of a same interposer collapse versus when inner solder bumps/balls of the interposer collapse. Alternatively, an attempt is made to uniformly collapse bumps/balls a same approximate distance from the center of the array at the same time.

Here, with ambient heating, solder bump/balls within the inner portions of the array may heat more slowly than the outer portions of the array. If the solder balls fail to collapse in a uniform way, the weight of an interposer 721 could cause the interposer to lean or list (although extended heating should cause the interposer to eventually settle correctly). The solder balls/bumps underneath the die 706 should be designed to approximately match the collapse dynamics of the interposer solder bumps/balls (although, again, an extended elevated temperature range should ensure that all solder bumps/balls eventually collapse).

In another embodiment, after an interposer 721 is resting on the bump/ball array, the exposed upper faces of the square wires of the interposer 721 are put in contact with a hot iron that uniformly heats each of the wires approximately equally over time. In a further embodiment, the hot iron is applied after the die's solder balls/bumps have been collapsed and the die 706 is fully mounted to the lower substrate.

By way of thermal conduction of the iron's heat through the square wires themselves, the respective temperatures of the lower faces of the square wires heat to approximately same temperatures over time and uniformly collapse their respective solder balls at approximately the same time. In an embodiment, the iron has a specially structured face having an array of blunt tips where each tip makes individual contact with its respective one of the wires to ensure that the uniform heating of all the wires to approximately same temperatures over time.

After the interposers 721 and die 706 are mounted on the lower substrate 701, as observed in FIGS. 7b and 7c, a top lid 750 for the lower package is placed over the lower die 706 and interposers 721 and sealed to the bottom substrate 701 to hermetically seal the lower die 706 within the lower package. FIG. 7b shows a side view. FIG. 7c shows a top down view.

In the particular embodiment of FIGS. 7b and 7c, a compound mold is not present in the spaces 752 between the die and the interposers. As discussed above with respect to FIG. 5b, the top side lid 750 may have openings 751 to expose the upper faces of the interposers 721 which act as the topside I/O for the lower package. In such embodiments, one or more outer perimeter layers of the stacked wires of the interposers 721 are not used an electrical contacts but rather as a landing area for the topside lid 750. Here, an adhesive may be applied on the landing area to ensure hermetic sealing of the lower package around the openings 751 in the lid where the interposers are exposed.

As observed in FIGS. 7d and 7e, the I/Os on the underside of the upper package 740 are aligned and mounted to the interposers 721. Again, solder bumps/balls may be used to form the electrical connection between the upper package 740 and the interposers 721. The solder bumps/balls may be preformed on the I/Os of the upper package, the upper faces of the interposers or some combination of both. After the upper package 740 is aligned and mounted, the structure is heated to collapse the solder balls and affix the upper package 740 to the lower package.

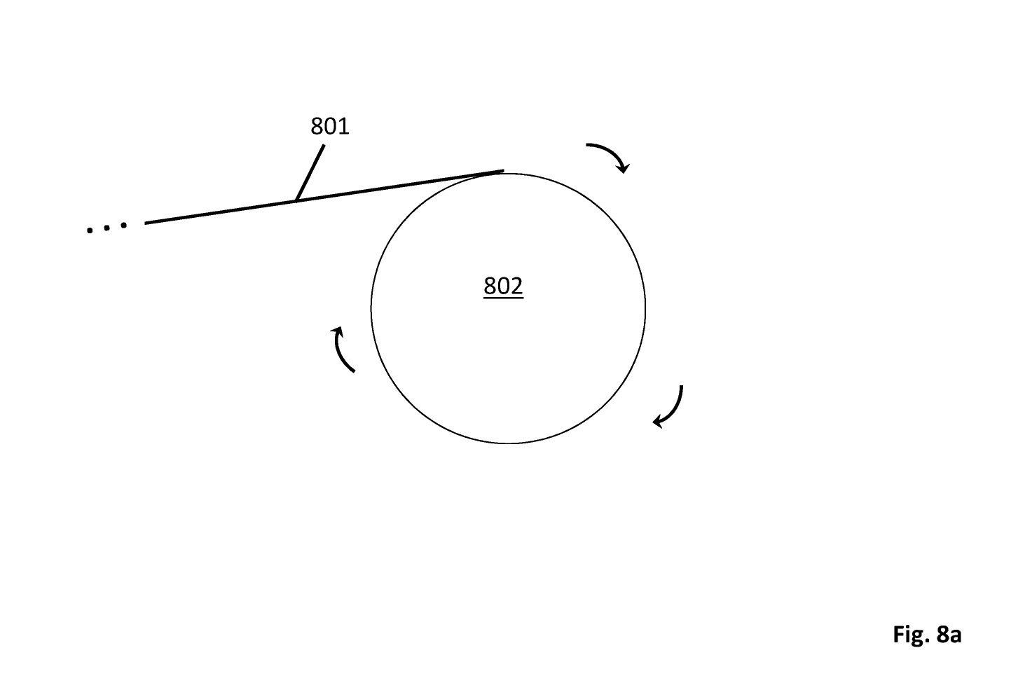

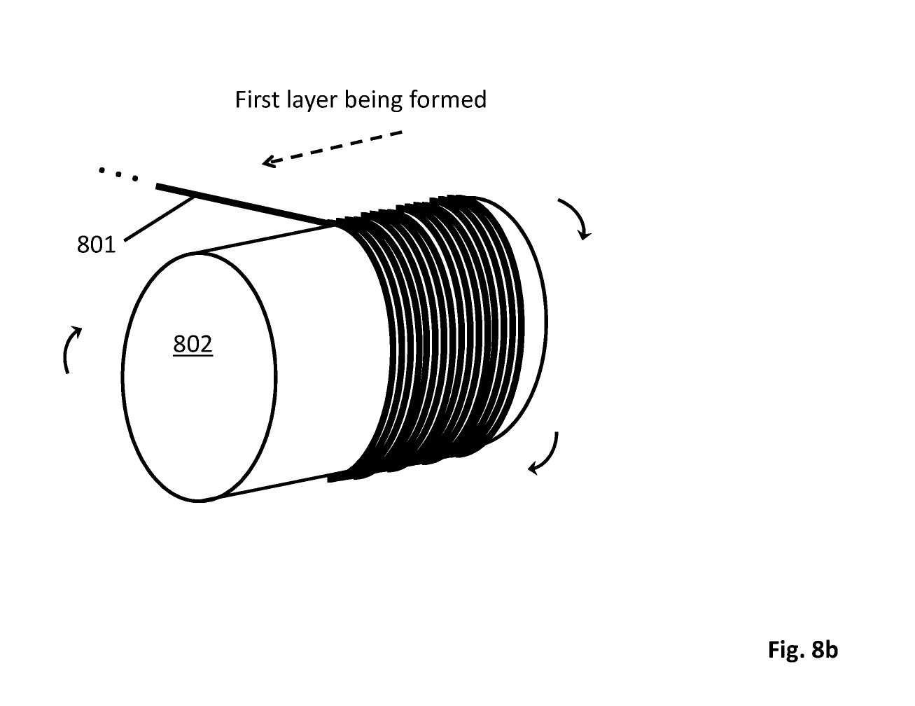

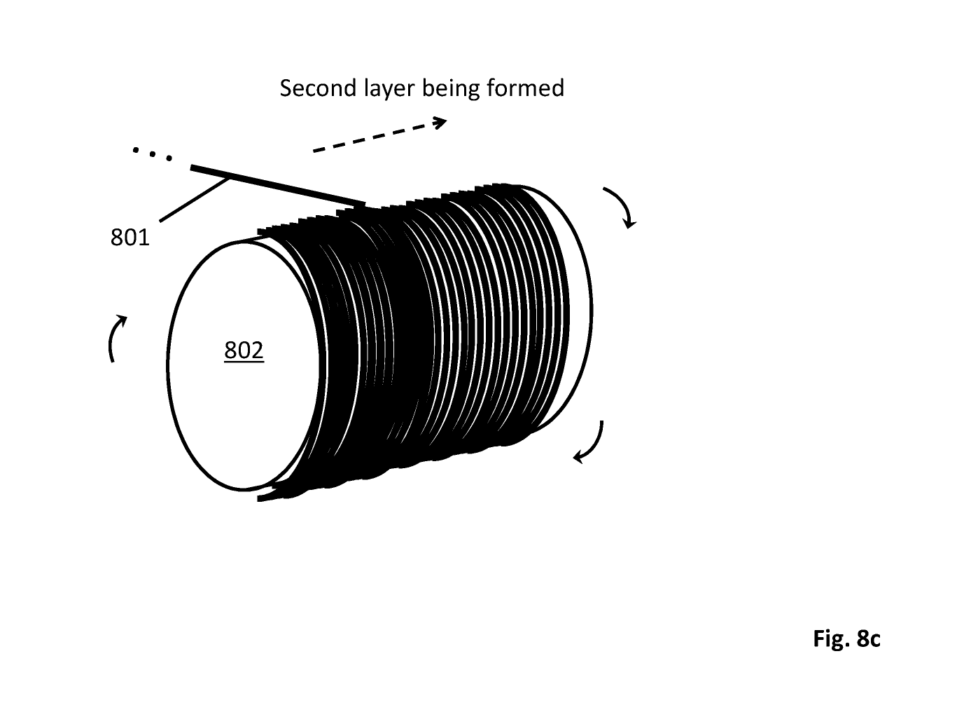

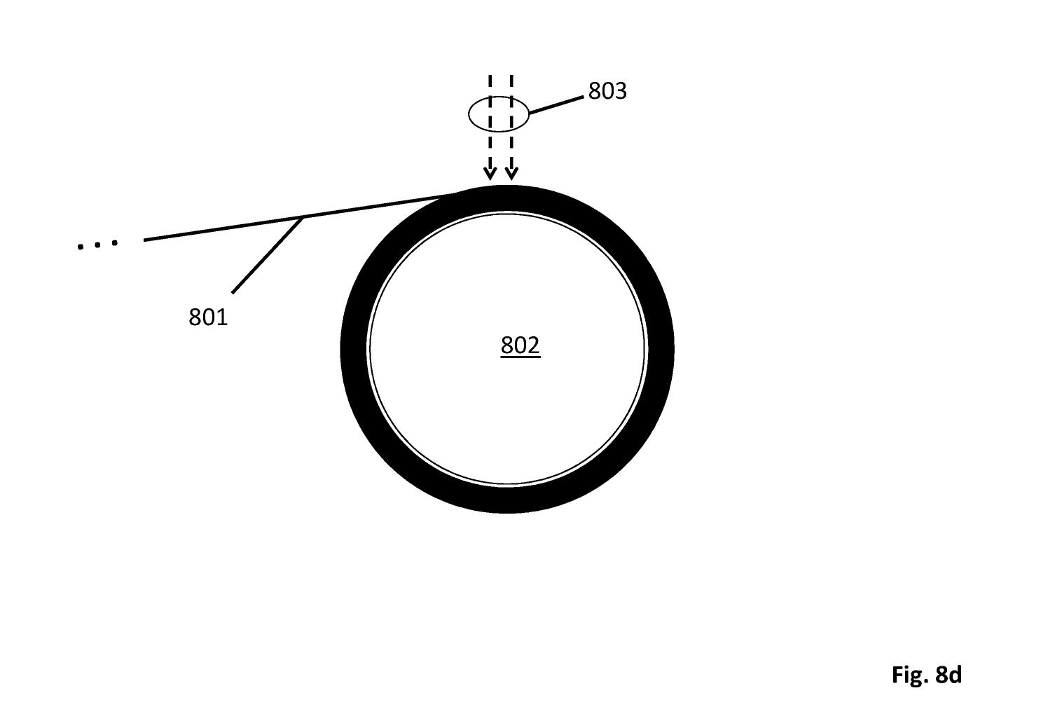

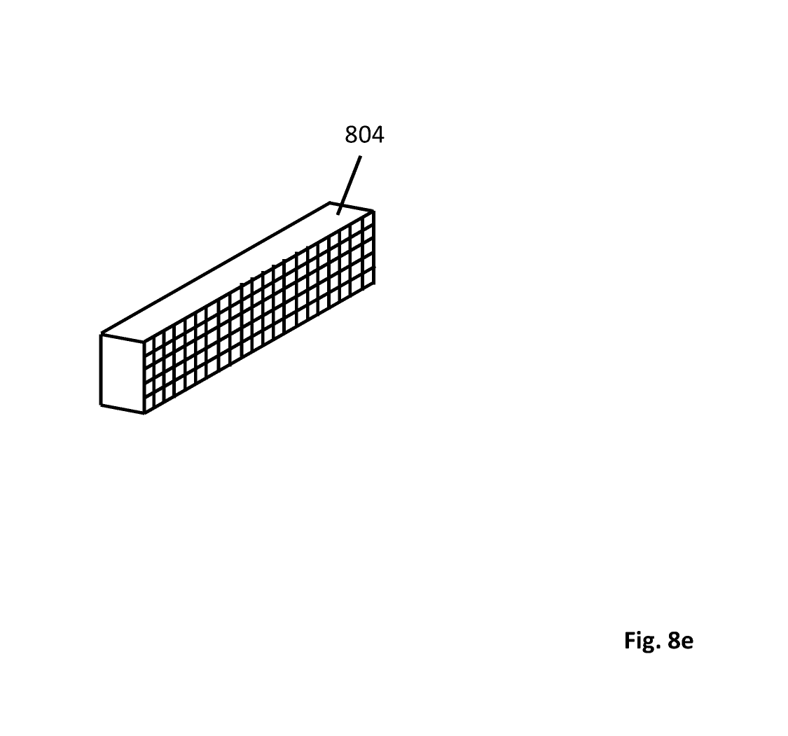

FIGS. 8a through 8e pertain to a method for forming an interposer. As observed in FIG. 8a, a long run length of a single square wire 801 is affixed to an end of a spool 802 . The spool is gradually spun to wind the copper wire across the spool as observed in FIGS. 8b through 8c. During the winding, some backward tension is applied to the wire 801 to wind it tightly on the spool and/or some downward and sideways pressure is applied to the wire to tightly pack it next to its neighboring and lower winds.

A new layer of copper wire is applied to the spool each time the lateral movement of the wire as it is wound switches direction (leftwise or rightwise) across the width of the spool. Eventually, enough windings of the spool will have transpired to correspond to the number of layers called for in the design of the interposer.

Referring to FIGS. 8d and 8e, after the winding of the wire 801 has been completed, the wound spool of tightly packed square wires is sliced into multiple slices along cutting lines such as cutting line pair 803. Here, the section of the wound wire between a pair of cutting lines such as cutting lines 803 forms a separate interposer 804 as slice of the wound wire. Note that for a sufficiently large spool radius, the slices should be sufficiently rectangular rather than wedge or arc shaped. In various embodiments, a diamond saw is used to slice the packed wires.

Although embodiments above have stressed square wires it is pertinent to note that other shapes wires may also be used without departing significantly from the spirit of the enclosed teachings. For example, instead of square wires, wires having any of a triangular, pentagonal, hexagonal, or octagonal cross section may be packed together to form an interposer. That is, more generally, the cross sections of the wires may be a polygon.

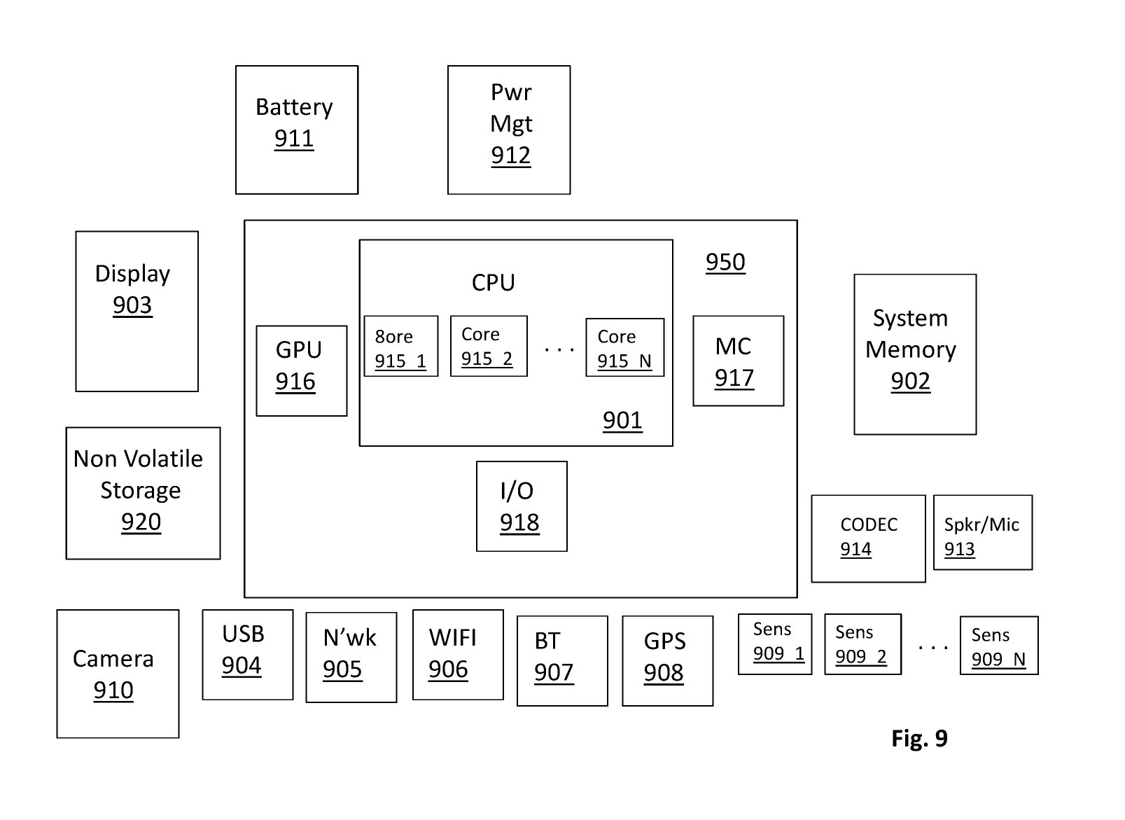

FIG. 9 shows a depiction of an exemplary computing system 900 such as a personal computing system (e.g., desktop or laptop) or a mobile or handheld computing system such as a tablet device or smartphone, or, a larger computing system such as a server computing system. As observed in FIG. 9, the basic computing system may include a central processing unit 901 (which may include, e.g., a plurality of general purpose processing cores and a main memory controller disposed on an applications processor or multi-core processor), system memory 902, a display 903 (e.g., touchscreen, flat-panel), a local wired point-to-point link (e.g., USB) interface 904, various network I/O functions 905 (such as an Ethernet interface and/or cellular modem subsystem), a wireless local area network (e.g., WiFi) interface 906, a wireless point-to-point link (e.g., Bluetooth) interface 907 and a Global Positioning System interface 908, various sensors 909_1 through 909_N (e.g., one or more of a gyroscope, an accelerometer, a magnetometer, a temperature sensor, a pressure sensor, a humidity sensor, etc.), a camera 910, a battery 911, a power management control unit 912, a speaker and microphone 913 and an audio coder/decoder 914.

An applications processor or multi-core processor 950 may include one or more general purpose processing cores 915 within its CPU 901, one or more graphical processing units 916, a memory management function 917 (e.g., a memory controller) and an I/O control function 918. The general purpose processing cores 915 typically execute the operating system and application software of the computing system. The graphics processing units 916 typically execute graphics intensive functions to, e.g., generate graphics information that is presented on the display 903. The memory control function 917 interfaces with the system memory 902.

Each of the touchscreen display 903, the communication interfaces 904-907, the GPS interface 908, the sensors 909, the camera 910, and the speaker/microphone codec 913, 914 all can be viewed as various forms of I/O (input and/or output) relative to the overall computing system including, where appropriate, an integrated peripheral device as well (e.g., the camera 910). Depending on implementation, various ones of these I/O components may be integrated on the applications processor/multi-core processor 950 or may be located off the die or outside the package of the applications processor/multi-core processor 950.

The computing system 900 may include a package on package structure having interposers composed of packed square metal wires as the package to package interconnect embodiments of which have been described at length above. The semiconductor die in either the upper or lower package may be any kind of semiconductor die. In one embodiment a system on chip having processing cores and a system memory controller is the lower die and a memory chip used for the system memory is the upper die. In yet another embodiment the lower die includes a memory controller and the upper die includes a memory chip. In various other embodiments at least one of the upper and lower die includes primarily analog circuitry. In yet other embodiments, at least one of the upper die includes is an application specific integrated circuits (ASIC). In still other embodiments at least one of the upper and lower die is any of a programmable logic device (PLD), a digital signal processor (DSP), or a field programmable gate array (FPGA).

An apparatus has been described. The apparatus includes a package on package structure. The package on package structure includes an interposer to implement electrical interconnections between an upper package of the package on package structure and a lower package of the package on package structure. The interposer includes packed wires where the packed wires have respective polygonal cross sections.

In various embodiments of the apparatus the packed wires include copper wires. In various embodiments of the apparatus respective ones of the packed wires include an insulating jacket. In various embodiments of the apparatus an adhesive is present between respective insulating jackets of respective ones of the packed wires. In various embodiments of the apparatus the packed wires include packed square wires. In various embodiments of the apparatus the packed wires have any of the following cross sectional shapes: triangular; pentagonal; hexagonal; octagonal. In various embodiments of the apparatus a compound mold surrounds a lower die of the lower package. In various embodiments of the apparatus empty space surrounds a lower die of the lower package.

A computing system has been described. The computing system includes a plurality of processing cores. The computing system includes a system memory controller. The computing system includes a system memory coupled to the memory controller. The computing system includes a network interface. The computing system includes a package on package structure. The package on package structure includes an interposer to implement electrical interconnections between an upper package of the package on package structure and a lower package of the package on package structure. The interposer includes packed wires where the packed wires have respective polygonal cross sections.

In various embodiments of the computing system the packed square wires comprise copper. In various embodiments of the computing system respective ones of the packed wires include an insulating jacket. In various embodiments of the computing system an adhesive is present between respective insulating jackets of respective ones of the packed wires. In various embodiments of the computing system the packed wires include packed square wires. In various embodiments of the computing system the packed wires have any of the following cross sectional shapes: triangular; pentagonal; hexagonal; octagonal. In various embodiments of the computing system a compound mold surrounds a lower die of the lower package. In various embodiments of the computing system empty space surrounds a lower die of the lower package.

A method has been described. The method includes building a lower package structure for a package-on-package structure. The lower package structure includes an interposer disposed on a substrate of the lower package structure. The interposer is composed of packed polygonal wires.

In various embodiments of the method the method further includes affixing an upper package structure on the lower package structure such that lower I/Os of the upper package structure align with upper surfaces of respective ones of the polygonal wires. In various embodiments of the method the method further includes building the interposer. In various embodiments of the method the polygonal wires have any of the following cross sectional shapes: triangular; square; pentagonal; hexagonal; octagonal.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a package on package structure comprising an interposer to implement electrical interconnections between an upper package of the package on package structure and a lower package of the package on package structure, the interposer comprising packed wires, the packed wires having respective polygonal cross sections.

2. The apparatus of claim 1 wherein the packed wires comprise copper wires.

3. The apparatus of claim 1 wherein respective ones of the packed wires comprise an insulating jacket.

4. The apparatus of claim 3 wherein an adhesive is present between respective insulating jackets of respective ones of the packed wires.

5. The apparatus of claim 1 wherein the packed wires comprise packed square wires.

6. The apparatus of claim 1 wherein the packed wires have any of the following cross sectional shapes:
triangular;
pentagonal;
hexagonal;
octagonal.

7. The apparatus of claim 1 wherein a compound mold surrounds a lower die of the lower package.

8. The apparatus of claim 1 wherein empty space surrounds a lower die of the lower package.

9. A computing system, comprising:
a plurality of processing cores;
a system memory controller;
a system memory coupled to the memory controller;
a network interface;
a package on package structure comprising an interposer to implement electrical interconnections between an upper package of the package on package structure and a lower package of the package on package structure, the interposer comprising packed wires, the packed wires have respective polygonal cross sections.

10. The computing system of claim 9 wherein the packed wires comprise copper wires.

11. The computing system of claim 9 wherein respective ones of the packed wires comprise an insulating jacket.

12. The computing system of claim 11 wherein an adhesive is present between respective insulating jackets of respective ones of the packed wires.

13. The computing system of claim 9 wherein the packed wires comprise packed square wires.

14. The computing system of claim 9 wherein the packed wires have any of the following cross sectional shapes:
triangular;
pentagonal;
hexagonal;
octagonal.

15. The computing system of claim 9 wherein a compound mold surrounds a lower die of the lower package.

16. The computing system of claim 9 wherein empty space surrounds a lower die of the lower package.

17. A method, comprising:
building a lower package structure for a package-on-package structure, the lower package structure including an interposer disposed on a substrate of the lower package structure, the interposer composed of packed polygonal wires,

18. The method of claim 17 further comprising affixing an upper package structure on the lower package structure such that lower I/Os of the upper package structure align with upper surfaces of respective ones of the polygonal wires.

19. The method of claim 17 further comprising building the interposer.

20. The method of claim 17 wherein the polygonal wires have any of the following cross sectional shapes:
triangular;
square;
pentagonal;
hexagonal;
octagonal.
